(19) United States
(12) Patent Application Publication
(10) Pub. No.: US 2014/0152379 A1
(43) Pub. Date: Jun. 5, 2014

(54) CAPACITOR, CHARGE PUMP CIRCUIT, AND SEMICONDUCTOR DEVICE

(71) Applicant: RENESAS ELECTRONICS CORPORATION, Kanagawa (JP)

(72) Inventors: Toshio FUJIMOTO, Kangawa (JP); Takashi ITO, Kanagawa (JP)

(73) Assignee: RENESAS ELECTRONICS CORPORATION, Kanagawa (JP)

(21) Appl. No.: 14/089,489

(22) Filed: Nov. 25, 2013

(30) Foreign Application Priority Data
Nov. 28, 2012 (JP) 2012-259431

(51) Int. Cl. H01L 49/02; H02M 3/07

(52) U.S. Cl. CPC H01L 28/60; H02M 3/07
USPC 327/536; 257/532

(57) ABSTRACT

There is provided a capacitor with a reduced layout area. A capacitor has an electrode EL1 formed by using a first polysilicon layer, an electrode EL2 formed by using a second polysilicon layer over the first polysilicon layer, and electrodes EL3 to EL6 formed by using second through fifth metal wiring layers over the second polysilicon layer. An N-type well and the electrode EL1 make up a capacitor element 11, the electrodes EL1, EL2 make up a capacitor element 12, and the electrodes EL3 to EL6 make up a capacitor element 13. The capacitor elements 11 to 13 are coupled in parallel between terminals T1, T2.

### CROSS-REFERENCE TO RELATED APPLICATIONS

The disclosure of Japanese Patent Application No. 2012-259431 filed on Nov. 28, 2012 including the specification, drawings and abstract is incorporated herein by reference in its entirety.

### BACKGROUND

The present invention relates to a capacitor, a charge pump circuit, and a semiconductor device and can be used suitably for a flash memory having a charge pump circuit.

Until now, a flash memory is provided with a charge pump circuit to generate a high voltage for rewriting data into memory cells. A charge pump circuit includes multiple diodes and multiple capacitors. The multiple diodes are, for example, coupled in series between a power supply voltage line and an output terminal. One end electrode of each capacitor is coupled to a node between two diodes. The other end electrode of each of capacitors corresponding to odd stages of diodes receives a first clock signal. The other end electrode of each of capacitors corresponding to even stages of diodes receives a second clock signal. When the first and second clock signals rise from “Low” level to “High” level alternately, a voltage at the cathode of the multiple diodes rises in turn and a high voltage is output from the output terminal.

In Patent Document 1, a capacitor having a transistor structure and a capacitor having a dual gate type transistor structure are disclosed. In Patent Document 2, a capacitor having an interdigital electrode structure is disclosed.

### RELATED ART DOCUMENTS

### Patent Documents

[Patent Document 1] Japanese Published Unexamined Patent Application No. 2012-23177
[Patent Document 2] Japanese Published Unexamined Patent Application No. 2008-130683

### SUMMARY

In the charge pump circuit as mentioned above, the multiple capacitors are required to have an equal capacitance value. Because a high voltage is applied to a capacitor corresponding to a diode nearer to the output terminal, a high voltage withstanding capacitor needs to be used as such capacitor. For instance, through the use of ordinary voltage withstanding capacitors, to provide a high voltage withstanding capacitor having the same capacitance value as that of an ordinary voltage withstanding capacitor and a withstand voltage doubled that of the latter capacitor, it is needed to use four ordinary voltage withstanding capacitors (see FIG. 1). Therefore, there has been a problem that the layout area of the charge pump circuit increases.

Other problems and novel features will become apparent from the following description in the present specification and the accompanying drawings.

According to one embodiment, in a capacitor of the present application, a capacitor having a MIM (Metal Insulator Metal) structure is disposed over a capacitor having a similar structure to a dual gate type transistor. In the latter capacitor, first and second polysilicon layers are deposited with an insulation film in between over a well area.

According to the one embodiment, it is possible to realize a capacitor and a charge pump circuit with a reduced layout area.

### BRIEF DESCRIPTION OF THE DRAWINGS

FIG. 1 is a circuit diagram depicting a configuration of a charge pump circuit which is presented as comparison example 1 to a first embodiment of the present application.

FIG. 2 is a diagram presenting the waveforms of two clocks presented in FIG. 1.

FIGS. 3A and 3B are diagrams depicting the structure of an ordinary voltage withstanding capacitor depicted in FIG. 1.

FIGS. 4A and 4B are diagrams depicting the structure of a high voltage withstanding capacitor depicted in FIG. 1.

FIGS. 5A and 5B are diagrams depicting the structure of an ordinary voltage withstanding capacitor included in a charge pump circuit which is presented as comparison example 2 to the first embodiment of the present application.

FIGS. 6A and 6B are diagrams depicting the structure of a high voltage withstanding capacitor included in the charge pump circuit described with FIGS. 5A and 5B.

FIG. 7 is a circuit diagram depicting a configuration of a charge pump circuit according to the first embodiment of the present application.

FIGS. 8A and 8B are diagrams depicting the structure of an ordinary voltage withstanding capacitor depicted in FIG. 7.

FIG. 9 is a plan view depicting the structure of the capacitor depicted in FIGS. 8A and 8B.

FIG. 10 is a perspective view depicting the structure of the capacitor depicted in FIG. 8.

FIGS. 11A and 11B are diagrams depicting the structure of a high voltage withstanding capacitor depicted in FIG. 7.

FIG. 12 is a plan view depicting the structure of the capacitor depicted in FIGS. 11A and 11B.

FIG. 13 is a perspective view depicting the structure of the capacitor depicted in FIG. 11.

FIGS. 14A and 14B are diagrams depicting an example of modification to the first embodiment.

FIG. 15 is a circuit diagram depicting a configuration of a charge pump circuit according to a second embodiment of the present application.

FIGS. 16A and 16B is a cross-sectional diagram depicting the structure of a high voltage withstanding capacitor depicted in FIG. 15.

FIG. 17 is a circuit diagram depicting a configuration of a charge pump circuit according to a third embodiment of the present application.

FIG. 18 is a diagram presenting the waveforms of four clock signals presented in FIG. 17.

FIG. 19 is a block diagram depicting a configuration of a microcomputer according to a fourth embodiment of the present application.

FIG. 20 is a block diagram depicting a configuration of a flash memory depicted in FIG. 19.

FIG. 21 is a block diagram depicting a configuration of a power supply circuit depicted in FIG. 20.

### DETAILED DESCRIPTION

To facilitate understanding of the present application, descriptions are provided for comparison examples before describing embodiments of the invention.

### Comparison Example 1

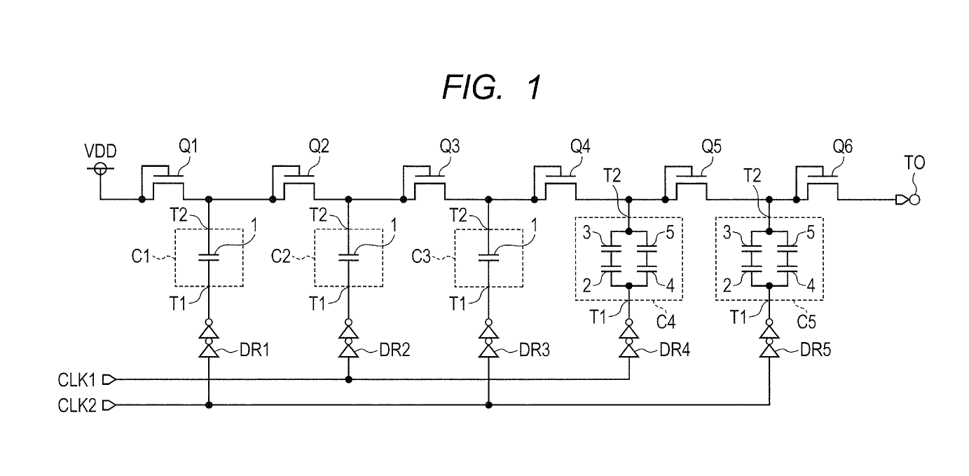

FIG. 1 is a circuit diagram depicting a configuration of a charge pump circuit which is presented as comparison example 1 to a first embodiment of the present application. In FIG. 1, this charge pump circuit has multiple (six, as depicted) N-channel MOS transistors Q1 to Q6, five capacitors C1 to C5, five drivers DR1 to DR5, and an output terminal TO.

The N-channel MOS transistors Q1 to Q6 are coupled in series between a power supply voltage VDD and the output terminal TO. The gates of the transistors Q1 to Q6 are coupled to the sources of the transistors Q1 to Q6, respectively. Each of the transistors Q1 to Q6 operates as a diode; its gate and drain act as an anode and its source acts as a cathode. Each of the N-channel MOS transistors Q1 to Q6 is used to transfer electric charge.

One end terminals T1 of the capacitors C1 to C5 receive clock signals output from the drivers DR1 to DR5, respectively, and their other end terminals T2 are coupled to the sources of the transistors Q1 to Q5, respectively. The capacitors C1 to C3 each are ordinary voltage withstanding capacitors and the capacitors C4, C5 each are high voltage withstanding capacitors.

A clock signal CLK2 is supplied to odd-numbered drivers DR1, DR3, DR5. A clock signal CLK1 is supplied to even-numbered drivers DR2, DR4. Each of the drivers DR1 to DR5 is a buffer including even stages (e.g. two stages) of inverters coupled in series and transfers a clock signal CLK to the source of its corresponding transistor Q.

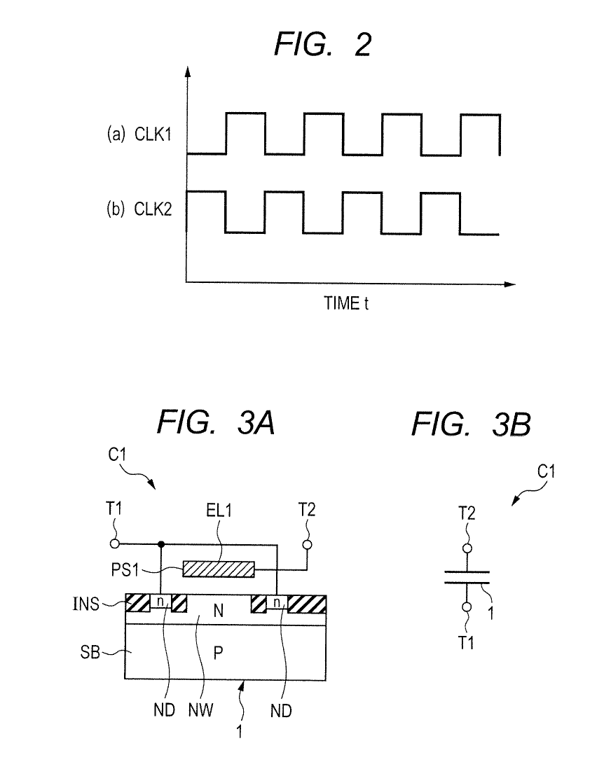

The clock signals CLK1 and CLK2 are mutually complementary signals, as can be seen in FIGS. 2A and 2B. That is, the phases of the clock signals CLK1, CLK2 shift by 180 degrees from each other. When the clock signal CLK1 changes to “High” level, the clock signal CLK 2 changes to “Low” level. When the clock signal CLK1 changes to “Low” level, the clock signal CLK 2 changes to “High” level.

Then, operation of this charge pump circuit is described. In FIG. 1, when changing the clock signal CLK1 to “High” level and the clock signal CLK2 to “Low” level, capacitance coupling of the capacitors C1 to C5 causes the source voltage of the transistors Q1, Q3, Q5 to fall and the source voltage of the transistors Q2, Q4 to rise. Thereby, through a line from the power supply voltage VDD, current flows via the transistor Q1 to the capacitor C1, and the capacitor C1 is charged. Current also flows through the transistors Q3, Q5 by which the charges of the capacitors C2, C4 are transferred to the capacitors C3, C5, respectively.

Then, when changing the clock signal CLK1 to “Low” level and the clock signal CLK2 to “High” level, capacitance coupling of the capacitors C1 to C5 causes the source voltage of the transistors Q1, Q3, Q5 to rise and the source voltage of the transistors Q2, Q4 to fall. Thereby, current flows through the transistors Q2, Q4, Q6 by which the charges of the capacitors C1, C3 are transferred to the capacitors C2, C4, respectively, and the charge of the capacitor C5 is supplied to the output terminal TO. This operation is repeated and the voltage of the output terminal TO gradually rises.

The voltage of the output terminal TO is compared to a target voltage by a comparator (not depicted). When the voltage of the output terminal TO becomes equal to or more than the target voltage, the clock signals CLK1, CLK2 are shut off and the operation of the charge pump circuit is stopped. When the voltage of the output terminal TO becomes lower than the target voltage, the clock signals CLK1, CLK2 are supplied and the operation of the charge pump circuit is restarted. In this way, the voltage of the output terminal TO is maintained at the target voltage.

FIG. 3A is a cross-sectional diagram depicting the structure of an ordinary voltage withstanding capacitor C1 and FIG. 3B is a schematic depicting the circuitry of the capacitor C1. In FIGS. 3A and 3B, the capacitor C1 includes a capacitor element 1 and two terminals T1, T2. The capacitor element 1 is formed over the surface of a P-type silicon substrate SB. An N-type well NW is formed over the surface of the P-type silicon substrate SB and an electrode EL1 is formed over an area of the surface of the N-type well NW with a first insulation layer (not depicted) in between. The electrode EL1 is formed by using a first polysilicon layer PS1.

A ring-shaped insulation film INS is formed around the area that faces the electrode EL1 in the surface of the N-type well NW and a ring-shaped n-type impurity diffused layer ND is formed around the ring-shaped insulation film INS. The circumference of the n-type impurity diffused layer ND is surrounded by the insulation film INS. The n-type impurity diffused layer ND is coupled to one terminal T1 and the electrode EL1 is coupled to the other terminal T2. For example, the terminal T1 is coupled to a “Low” level side and the terminal T2 is coupled to a “High” level side.

The capacitor element 1 has a similar structure to a MOS transistor. The capacitor C1 has a capacitance value that is determined by the planar dimension of an area in which the electrode EL1 and the N-type well NW face each other, the distance between the electrode EL1 and the N-type well NW, and the permittivity (dielectric constant) of the insulation layer (not depicted). The capacitors C2, C3 each also have the same structure as the capacitor C1. The capacitors C1 to C3 have an equal capacitance value.

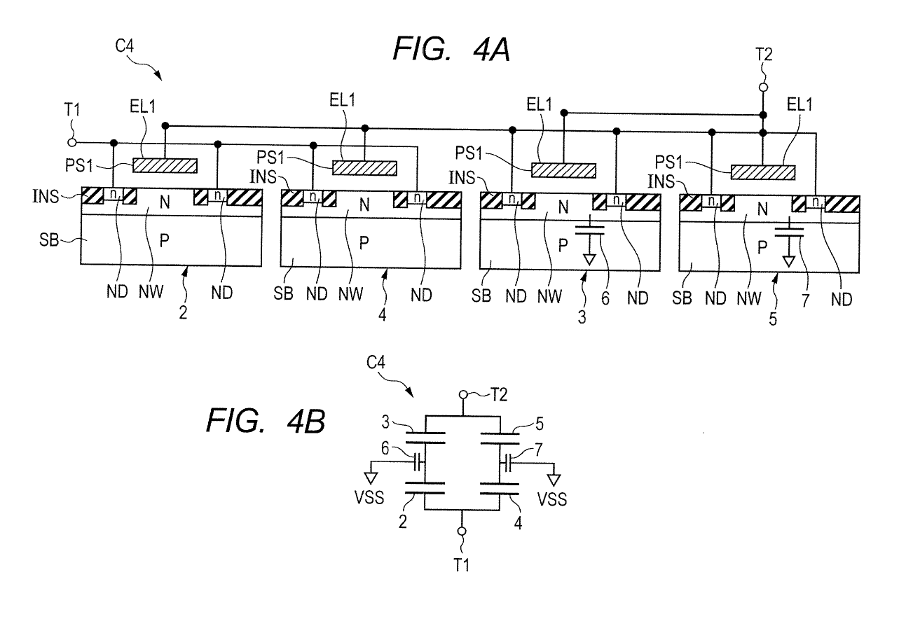

FIG. 4A is a cross-sectional diagram depicting the structure of a high voltage withstanding capacitor C4 and FIG. 4B is a schematic depicting the circuitry of the capacitor C4. In FIGS. 4A and 4B, the capacitor C4 includes four capacitor elements 2 to 5 and two terminals T1, T2. The capacitor elements 2, 3 are coupled in series between the terminals T1, T2. The capacitor elements 4, 5 are coupled in series between the terminals T1, T2. Each of the capacitor elements 2 to 5 has the same structure as the capacitor C1.

Both the n-type impurity diffused layers ND of the capacitor elements 2, 4 are coupled to the terminal T1. The electrodes EL1 of the capacitor elements 2, 4 and the n-type impurity diffused layers ND of the capacitor elements 3, 5 are inter-coupled. Both the electrodes EL1 of the capacitor elements 3, 5 are coupled to the terminal T2. For example, the terminal T1 is coupled to a “Low” level side and the terminal T2 is coupled to a “High” level side.

Theoretically, this capacitor C4 has the same capacitance value as that of the capacitor C1 and a withstand voltage that is twice as high as that of the capacitor C1. However, an actual capacitance value of the capacitor C4 becomes smaller than its theoretical value, since there are parasitic capacitances 6, 7 respectively between the N-type wells NW of the capacitor elements 3, 5 and ground voltage VSS lines. Therefore, in order to make the capacitance value of the capacitor C4 practically equivalent to the capacitance value of the capacitor C1, it is required to make the area occupied by each of the capacitor elements 2 to 5 larger than the area occupied by the capacitor C1. That is, the area occupied by the capacitor C4 becomes larger than four times the area occupied by the capacitor C1. The capacitor C5 also has the same structure as the capacitor C4.

### Comparison Example 2

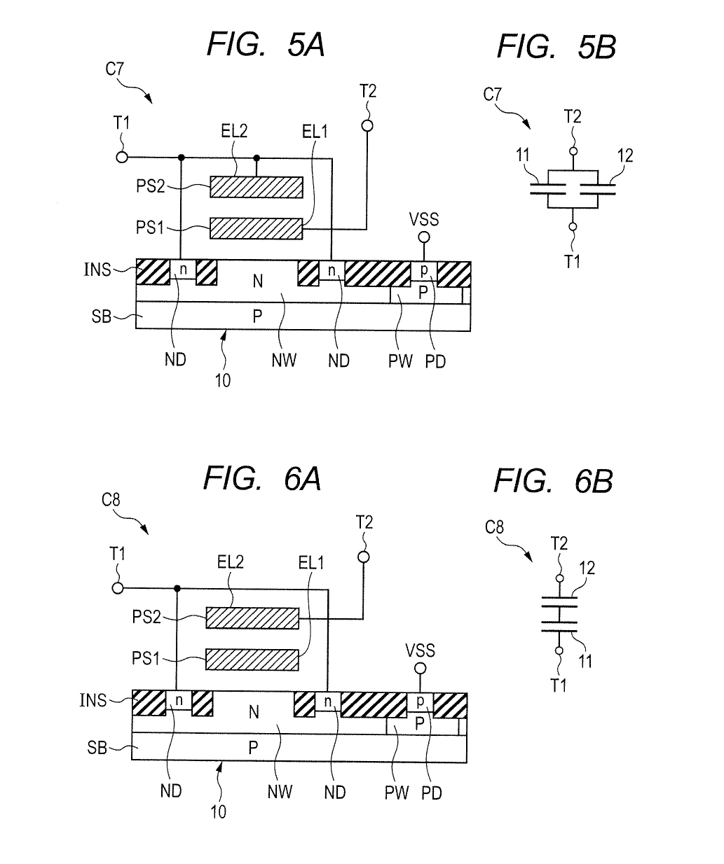

FIG. 5A is a cross-sectional diagram depicting the structure of an ordinary voltage withstanding capacitor C7 included in a charge pump circuit which is presented as comparison example 2 to the first embodiment and FIG. 5B is a schematic depicting the circuitry of the capacitor C7.

In FIGS. 5A and 5B, the capacitor C7 includes a capacitor element 10 and terminals T1, T2. The capacitor element 10 is formed over the surface of a P-type silicon substrate SB. An N-type well NW and a P-type well PW are formed over the surface of the P-type silicon substrate SB. An electrode EL1 is formed over an area of the surface of the N-type well NW with a first insulation layer (not depicted) in between and an electrode EL2 is formed over the electrode EL1 with a second insulation layer (not depicted) in between. The electrode EL1 is formed by using a first polysilicon layer PS1 and the electrode EL2 is formed by using a second polysilicon layer PS2. That is, over the well area, a layered capacitor is formed by using the first and second polysilicon layers deposited with an insulation film in between.

A ring-shaped insulation film INS is formed around the area that faces the electrode EL1 in the surface of the N-type well NW and a ring-shaped n-type impurity diffused layer ND is formed around the ring-shaped insulation film INS. The circumference of the n-type impurity diffused layer ND is surrounded by the insulation film INS. Besides, a p-type impurity diffused layer PD is formed in an area of the surface of the P-type well PW and the insulation film INS is formed around the p-type impurity diffused layer. A ground voltage VSS is applied to the p-type impurity diffused layer PD.

The capacitor element 10 includes two capacitor elements 11, 12. A capacitor element 11 has a first capacitance value that is determined by the planar dimension of an area in which the electrode EL1 and the N-type well NW face each other, the distance between the electrode EL1 and the N-type well NW, and the permittivity (dielectric constant) of the first insulation layer (not depicted). A capacitor element 12 has a second capacitance value that is determined by the planar dimension of an area in which the electrode EL1 and the electrode EL2 face each other, the distance between the electrode EL1 and the electrode EL2, and the permittivity (dielectric constant) of the second insulation layer (not depicted). The first capacitance value and the second capacitance value are equal. The capacitor element 10 has a similar structure to a flash memory transistor having dual gates.

In the ordinary voltage withstanding capacitor C7, the electrode EL2 and the n-type impurity diffused layer ND are coupled to one terminal T1 and the electrode EL1 is coupled to the other terminal T2. For example, the terminal T1 is coupled to a “Low” level side and the terminal T2 is coupled to a “High” level side. The capacitor C7 includes two capacitor elements 11, 12 coupled in parallel between the terminals T1, T2.

If the area occupied by the electrode EU of the capacitor C7 is equal to the area occupied by the electrode EL1 of the capacitor C1 depicted in FIGS. 3A and 3B, the capacitance value of the capacitor C7 will be twice as high as the capacitance value of the capacitor C1. If the area occupied by the electrode EL1 of the capacitor C7 is one-half of the area occupied by the electrode EL1 of the capacitor C1, the capacitance value of the capacitor C7 will be equal to the capacitance value of the capacitor C1. The capacitor C7 in which the area occupied by the electrode EL1 was reduced to one-half is, for example, used instead of each of the capacitors C1 to C3 in the charge pump circuit depicted in FIG. 1.

FIG. 6A is a cross-sectional diagram depicting the structure of a high voltage withstanding capacitor C8 included in the charge pump circuit which is presented as comparison example 2 to the first embodiment and FIG. 63 is a schematic depicting the circuitry of the capacitor C8. This capacitor C8 includes a capacitor element 10 and two terminals T1, T2.

In this capacitor C8, the n-type impurity diffused layer ND is coupled to one terminal T1 and the electrode EL2 is coupled to the other terminal T2. The electrode EL1 is put in a floating state. For example, the terminal T1 is coupled to a “Low” level side and the terminal T2 is coupled to a “High” level side. This capacitor C8 includes two capacitor elements 11, 12 coupled in series between the terminals T1, T2. In this capacitor C8, because the two capacitor elements 11, 12 are vertically stacked and coupled in series, parasitic capacitances 6, 7 as depicted in FIG. 43 can be ignored.

If the area occupied by the electrode EL1 of the capacitor C8 is equal to the area occupied by the electrode EL1 of the capacitor C1 depicted in FIGS. 3A and 3B, the capacitance value of the capacitor C8 will be one-half of the capacitance value of the capacitor C1. If the area occupied by the electrode EL1 of the capacitor C8 is twice as much as the area occupied by the electrode EL1 of the capacitor C1, the capacitance value of the capacitor C8 will be equal to the capacitance value of the capacitor C1. The capacitor C8 in which the area occupied by the electrode EL1 was doubled is, for example, used instead of each of the capacitors C4, C5 in the charge pump circuit depicted in FIG. 1.

The area occupied by the capacitor C8 in which the area occupied by the electrode EL1 was doubled is one-half of the area occupied by the capacitor C4. Therefore, if charge pump circuits having the same current supplying capacity are configured as in comparison examples 1, 2, the area occupied by the capacitor components of the charge pump circuit of comparison example 2 amounts to only one-half of the area occupied by the capacitor components of the charge pump circuit of comparison example 1.

### First Embodiment

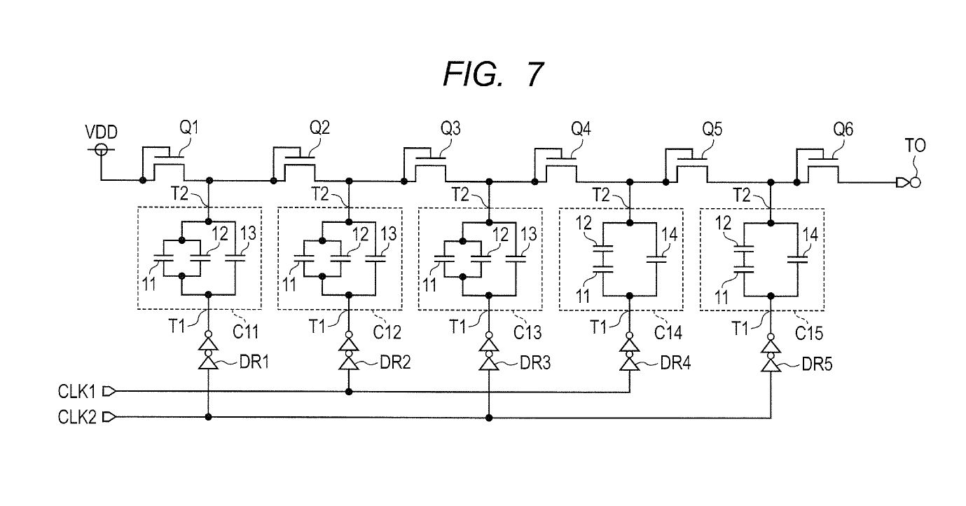

FIG. 7 is a circuit diagram depicting a configuration of a charge pump circuit according to the first embodiment of the present application; this figure is contrasted with FIG. 1. Referring to FIG. 7, this charge pump circuit differs from the charge pump circuit in FIG. 1 in the following respect: the capacitors C1 to C5 are replaced by capacitors C11 to C15, respectively.

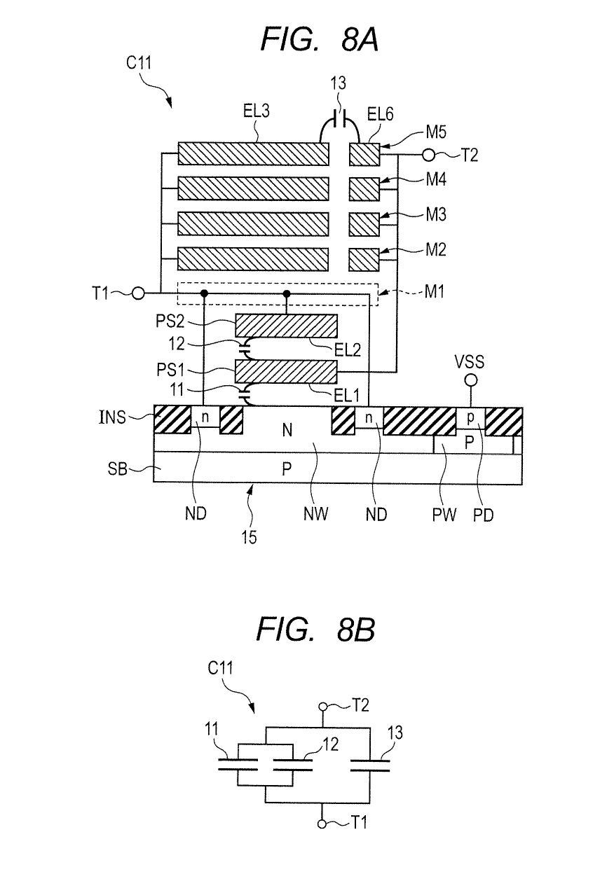

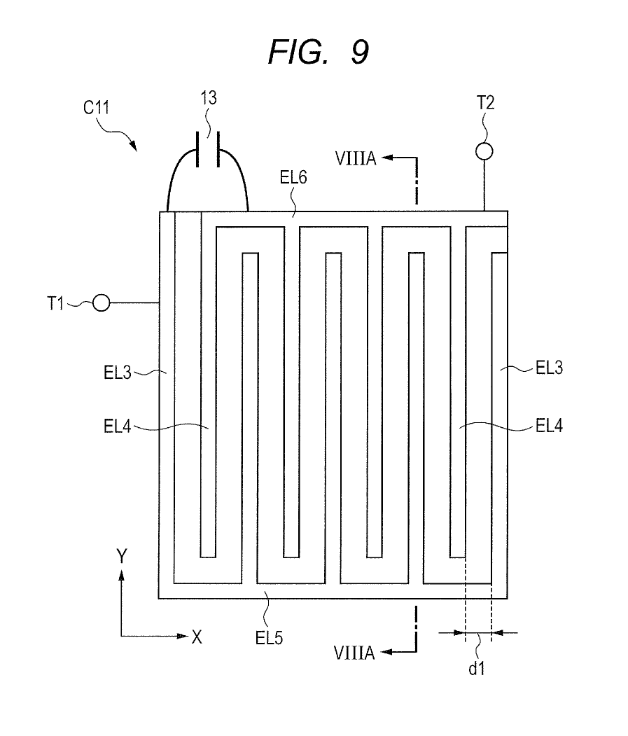

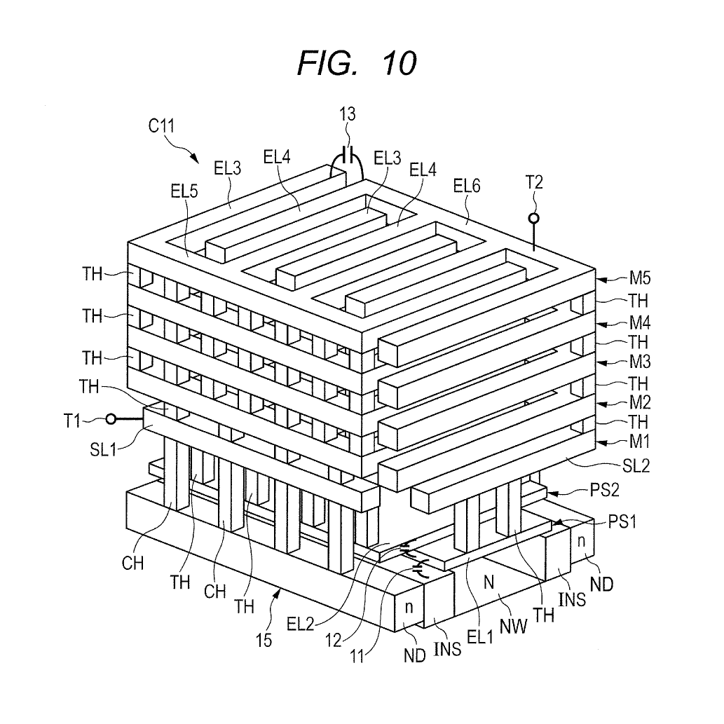

FIG. 8A is a cross-sectional diagram depicting the structure of an ordinary voltage withstanding capacitor C11; this figure is contrasted with FIG. 5A. FIG. 8B is a schematic depicting the circuitry of the capacitor C11; this figure is contrasted with FIG. 5B. FIG. 9 is an overhead view of the capacitor C11. FIG. 8A is the cross-sectional diagram taken along line VIIIA-VIIIA in FIG. 9. FIG. 10 is a perspective view depicting the structure of the capacitor C11.

Referring to FIGS. 8A and 8B through FIG. 10, the capacitor C11 includes a capacitor element 15 and two terminals T1, T2. The capacitor element 15 is configured by forming a capacitor element 13 over the capacitor element 10 depicted in FIG. 5A.

Over the surface of a silicon substrate SB, a first polysilicon layer PS1, a second polysilicon layer PS2, a first metal wiring layer M1, a second metal wiring layer M2, a third metal wiring layer M3, a fourth metal wiring layer M4, and a fifth metal wiring layer are formed in order and these layers are insulated from each other. As described previously, an electrode EL1 is formed by using the first polysilicon layer PS1 and an electrode EL2 is formed by using the second polysilicon layer PS2. Wiring lines SL1, SL2 for coupling the terminal T1 and the electrode EL2 among others are formed by using the first metal wiring layer M1.

By using each of the second through fifth metal wiring layers M2 to M5, multiple electrodes EL3, EL4 and electrodes EL5, EL6 are formed. Electrodes EL3, EL4 each extend in a Y direction. The electrodes EL3 and EL4 are arranged alternately in an X direction at right angles to the Y direction. The electrodes EL3 and EL4 are arranged, spaced by a predetermined interval d1. Electrodes EL5, EL6 each extend in the X direction. An electrode EL5 is disposed adjacent to one end side of the multiple electrodes EL3, EL4 and is coupled to one end of each electrode EL3. An electrode EL6 is disposed adjacent to the other end side of the multiple electrodes EL3, EL4 and is coupled to the other end of each electrode EL4. That is, the multiple electrodes EL3, EL4 and electrodes EL5, EL6 make up an interdigital electrode.

Every two of electrodes EL5 which are vertically stacked are coupled to each other by multiple through holes TH. Also, every two of electrodes EL6 which are vertically stacked are coupled to each other by multiple through holes TH. The electrodes EL3 to EL6 formed by using the second through fifth metal wiring layers M2 to M5 make up an ordinary voltage withstanding capacitor element 13. The capacitor element 13 has a third capacitance value that is determined by the planar dimension of an area in which the electrodes EL3, EL4 face each other, the distance d1 between the electrodes EL3, EL4, the permittivity (dielectric constant) of a third insulation layer (not depicted) between the electrodes EL3, EL4, and the number of the electrodes EL3, EL4 facing each other. The capacitor element 13 is called a MIM (Metal-Insulator-Metal) type capacitor element. If the third insulation layer between the electrodes EL3, EL4 is an oxide film, the capacitor element 13 is called a MOM (Metal-Oxide-Metal) type capacitor element.

In the ordinary voltage withstanding capacitor C11, an electrode EL2, an n-type impurity diffused layer ND, and each electrode EL5 (in other words, each electrode EL3) are coupled to the terminal T1 and an electrode EL 1 and each electrode EL6 (in other words, each electrode EL4) are coupled to the terminal T2. In FIG. 10, an electrode EL 5 formed by the second metal wiring layer M2 is coupled to a wiring line SL1 formed by the first metal wiring layer M1 via multiple through holes TH. The wiring line SL1 is coupled to an n-type impurity diffused layer ND via multiple contact holes CH and coupled to the electrode EL2 via multiple through holes TH. An electrode EL6 formed by the second metal wiring layer M2 is coupled to a wiring line SL2 formed by the first metal wiring layer M1 via multiple through holes TH. The wiring line SL2 is coupled to the electrode EL1 via multiple through holes TH.

For example, the terminal T1 is coupled to a “Low” level side and the terminal T2 is coupled to a “High” level side. The capacitor C11 includes three capacitor elements 11 to 13 coupled in parallel between the terminals T1, T2.

If the area occupied by the capacitor C11 is equal to the area occupied by the capacitor C1 depicted in FIGS. 3A and 3B and the capacitor elements 11, 12, 13 have an equal capacitance value, the capacitance value of the capacitor C11 will be three times as high as the capacitance value of the capacitor C1. If the area occupied by the capacitor C11 is one-third of the area occupied by the capacitor C7, the capacitance value of the capacitor C11 will be equal to the capacitance value of the capacitor C1. Capacitors C12, C13 each also have the same structure as the capacitor C11.

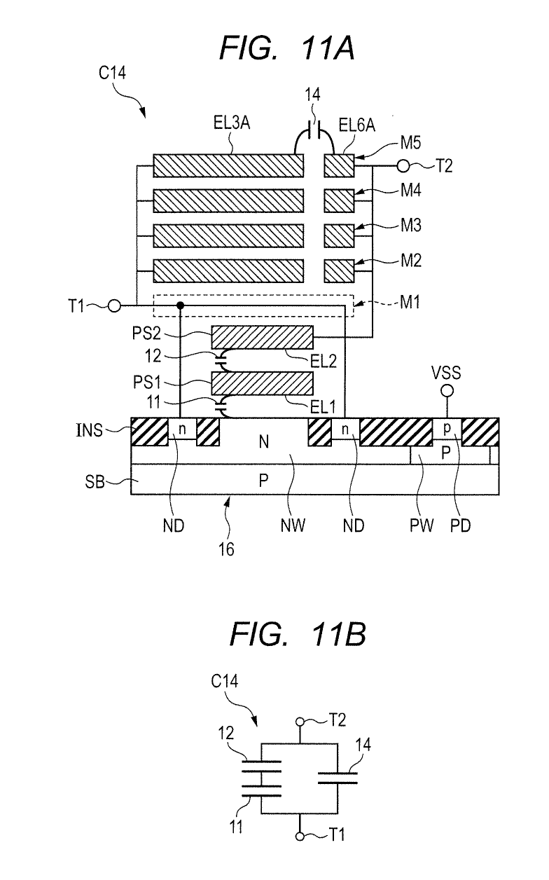

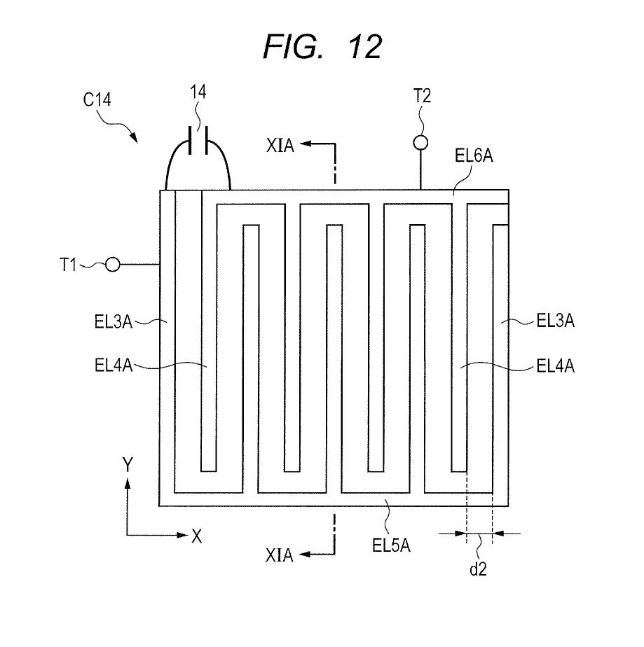

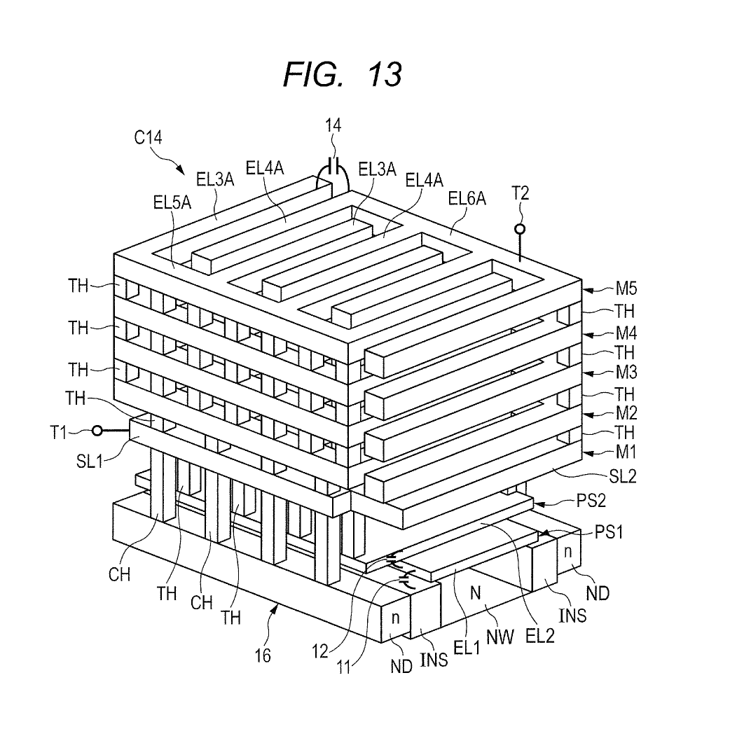

FIG. 11A is a cross-sectional diagram depicting the structure of a high voltage withstanding capacitor C14; this figure is contrasted with FIG. 8A. FIG. 11B is a schematic depicting the circuitry of the capacitor C14; this figure is contrasted with FIG. 8B. FIG. 12 is an overhead view of the capacitor C14. FIG. 11A is the cross-sectional diagram taken along line XIA-XIA in FIG. 12. FIG. 13 is a perspective view depicting the structure of the capacitor C14.

Referring to FIGS. 11A and 8B through FIG. 13, the capacitor C14 includes a capacitor element 16 and two terminals T1, T2. The capacitor element 16 is configured by replacing the ordinary voltage withstanding MIM-type capacitor element 13 in the capacitor element 15 by a high voltage withstanding MIM-type capacitor element 14.

By using each of the second through fifth metal wiring layers M2 to M5, multiple electrodes EL3A, EL4A and electrodes EL5A, EL6A are formed. Electrodes EL3A, EL4A each extend in the Y direction. The electrodes EL3A and EL4A are arranged alternately in the X direction. The electrodes EL3A and EL4A are arranged, spaced by a predetermined interval d2, where d2>d1. Electrodes EL5A, EL6A each extend in the X direction. An electrode EL5A is disposed adjacent to one end side of the multiple electrodes EL3A, EL4A and is coupled to one end of each electrode EL3A. An electrode EL6A is disposed adjacent to the other end side of the multiple electrodes EL3A, EL4A and is coupled to the other end of each electrode EL4A. That is, the multiple electrodes EL3A, EL4A and electrodes EL5A, EL6A make up an interdigital electrode.

Every two of electrodes EL5A which are vertically stacked are coupled to each other by multiple through holes TH. Also, every two of electrodes EL6A which are vertically stacked are coupled to each other by multiple through holes TH. The electrodes EL3A to EL6A formed by using the second through fifth metal wiring layers M2 to M5 make up a high voltage withstanding capacitor element 14. The capacitor element 14 has a fourth capacitance value that is determined by the planar dimension of an area in which the electrodes EL3A, EL4A face each other, the distance d2 between the electrodes EL3A, EL4A, the permittivity (dielectric constant) of a third insulation layer (not depicted) between the electrodes EL3A, EL4A, and the number of the electrodes EL3A, EL4A facing each other.

In this capacitor C14, an n-type impurity diffused layer ND and each electrode EL5A (in other words, each electrode EL3A) are coupled to the terminal T1 and an electrode EL2A and each electrode EL6A (in other words, each electrode EL4A) are coupled to the terminal T2. An electrode EL1 is put in a floating state. In FIG. 13, an electrode EL5A formed by the second metal wiring layer M2 is coupled to a wiring line SL1 formed by first metal wiring layer M1 via multiple through holes TH. The wiring line SL1 is coupled to an n-type impurity diffused layer ND via multiple contact holes CH. An electrode EL6A formed by the second metal wiring layer M2 is coupled to a wiring line SL2 formed by the first metal wiring layer M1 via multiple through holes TH. The wiring line SL2 is coupled to the electrode EL2 via multiple through holes TH.

For example, the terminal T1 is coupled to a “Low” level side and the terminal T2 is coupled to a “High” level side. This capacitor C14 includes two capacitor elements 11, 12 coupled in series between the terminals T1, T2 and a capacitor element 14 coupled between the terminals T1, T2.

If the area occupied by the capacitor C14 is equal to the area occupied by the capacitor C1 depicted in FIGS. 3A and 3B and the capacitance value of the capacitor element 14 is 0.4 times the capacitance value of each of the capacitor elements 11, 12, the capacitance value of the capacitor C14 will be 0.9 times the capacitance value of the capacitor C1. If the area occupied by the capacitor C14 is 1.11 times the area occupied by the capacitor C1, the capacitance value of the capacitor C14 will be equal to the capacitance value of the capacitor C1. A capacitor C15 also has the same structure as the capacitor C14.

Here, let us denote by S1 the area occupied by the capacitor components of the charge pump circuit of comparison example 1 employing an ordinary voltage withstanding capacitor C1 and a high voltage withstanding capacitor C4. Let us denote by S2 the area occupied by the capacitor components of the charge pump circuit of comparison example 2 employing an ordinary voltage withstanding capacitor C7 and a high voltage withstanding capacitor C8. And, let us denote by S3 the area occupied by the capacitor components of the charge pump circuit of the first embodiment employing an ordinary voltage withstanding capacitor C11 and a high voltage withstanding capacitor C14.

Given that the area occupied by the ordinary voltage withstanding capacitor C1 is assumed to be 1 and the area occupied by the high voltage withstanding capacitor C4 is assumed to be 4 in comparison example 1; the area occupied by the ordinary voltage withstanding capacitor C7 will be 0.5 and the area occupied by the high voltage withstanding capacitor C8 will be 2 in comparison example 2; and the area occupied by the ordinary voltage withstanding capacitor C11 will be 0.33 and the area occupied by the high voltage withstanding capacitor C14 will be 1.11 in the first embodiment.

Given that the charge pump circuit in each case is assumed to have five ordinary voltage withstanding capacitors and four high voltage withstanding capacitors; S1, S2, and S3 are calculated as follows: S1=1×5+4×4=21, S2=0.5×5+2×4=10.5, and S3=0.33×5+1.11×4=6.1. Hence, according to the first embodiment, the area occupied by the capacitor components of the charge pump circuit can be quite reduced than that in comparison examples 1 and 2.

Although, in the first embodiment, the electrodes EL1, EL2 are provided over the N-type well NW, the electrodes EL1, EL2 may be provided over the P-type well PW. In this case, for example, in FIG. 8A and FIG. 11A, N-type and P-type are reversed, n-type and p-type are reversed, and the power supply voltage VDD is applied instead of the ground voltage VSS.

Although, in the first embodiment, the description assumed a case where the capacitors C11 to C15 are applied to the charge pump circuit for generating a positive voltage, the capacitors C11 to C15 can also be applied to a charge pump circuit for generating a negative voltage. In this case, for example, in FIG. 7, the transistors Q1 to Q6 are coupled in series between the output terminal TO and a ground voltage VSS line.

Although, in the first embodiment, the electrodes EL3, EL4 are provided in place just over the electrodes EL1, EL2, the electrodes EL3, EL4 may be provided not exactly in place just over the electrodes EL1, EL2.

Although, in the first embodiment, the capacitor elements 13, 14 each are formed by using four metal wiring layers M2 to M5, but this is non-limiting, the capacitor elements 13, 14 each may be formed by using any one or two or more metal wiring layers.

Although, in the first embodiment, the capacitor elements 13, 14 each are formed so as to be arranged in an interdigital form, it is indisputable that they may be formed to be arranged in a form other than the interdigital form.

And now, a flash memory cell includes a floating gate and a control gate formed over the well. The floating gate and the control gate are formed by using the first polysilicon layer PS1 and the second polysilicon layer PS2, respectively. In a case where the flash memory cell and the charge pump circuit of the first embodiment are formed over the surface of a single silicon substrate, the electrodes EL1, EL2 of the capacitor elements 15, 16 each are formed by the same process as for the floating gate and the control gate of the flash memory cell. The electrodes EL3 to EL6, EL3A to EL6A of the capacitor elements 13, 14 are formed by the same process as for typical metal wiring lines.

And now, an FMONOS (Flash Metal Oxide Nitride Oxide Semiconductor) memory cell includes a first gate electrode and a second gate electrode formed over the well. The first gate electrode is formed by a wiring layer using the first polysilicon layer PS1. The second gate electrode is formed by a wiring layer using the second polysilicon layer PS2. In a case where the FMONOS memory cell and the charge pump circuit of the first embodiment are formed over the surface of a single silicon substrate, the electrodes EL1, EL2 of the capacitor elements 15, 16 each are formed by the same process as for the first and second electrodes of the FMONOS memory cell. The electrodes EL3 to EL6, EL3A to EL6A of the capacitor elements 13, 14 are formed by the same process as for typical metal wiring lines.

Although, in the first embodiment, the charge pump circuit has six transistors Q1 to Q6 for transferring electric charge and five capacitors C11 to C15, but this is non-limiting. The charge pump circuit may have N transistors for transferring electric charge (where N is an integer of 2 or more) and (N−1) capacitors. In this case, capacitors that are coupled to 1st through K-th series-coupling nodes (where K is an integer larger than 1 and smaller than (N−1)) from the side of the power supply voltage VDD line have the same structure as the capacitor Cu. Capacitors that are coupled to (K+1)-th through (N−1)-th series-coupling nodes have the same structure as the capacitor C14.

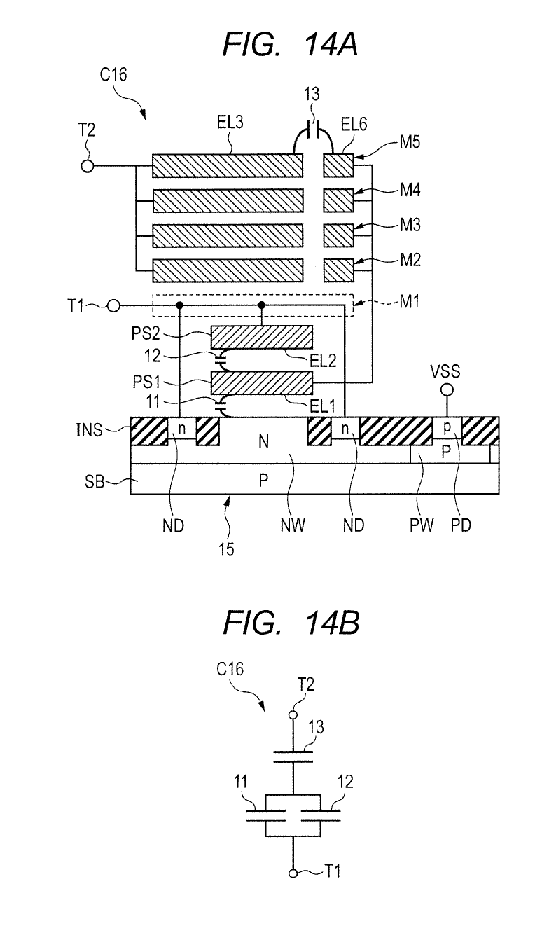

FIG. 14A is a cross-sectional diagram depicting the structure of a high voltage withstanding capacitor C16 which is presented as an example of modification to the first embodiment; this figure is contrasted with FIG. 8A. FIG. 14B is a schematic depicting the circuitry of the capacitor C16; this figure is contrasted with FIG. 8B. Referring to FIGS. 14A and 14B, the capacitor C16 includes a capacitor element 15 and two terminals T1, T2.

In the capacitor C16, an electrode EL2 and an n-type impurity diffused layer ND are coupled to the terminal T1, an electrode EL1 and each electrode EL6 (in other words, each electrode EL4) are inter-coupled, and each electrode EL5A (in other words, each electrode EL3) is coupled to the terminal T2. For example, the terminal T1 is coupled to a “Low” level side and the terminal T2 is coupled to a “High” level side. The capacitor C16 includes capacitor elements 11, 13 coupled in series between the terminals T1, T2 and a capacitor element 12 coupled in parallel with the capacitor element 11. This capacitor C16 is a high voltage withstanding capacitor, since the capacitor elements 11, 13 are coupled in series between the terminals T1, T2. This capacitor C16 is used instead of each of the capacitors C14, C15 in the charge pump circuit in FIG. 7. In this example of modification also, the same advantageous effects can be obtained as with the first embodiment.

### Second Embodiment

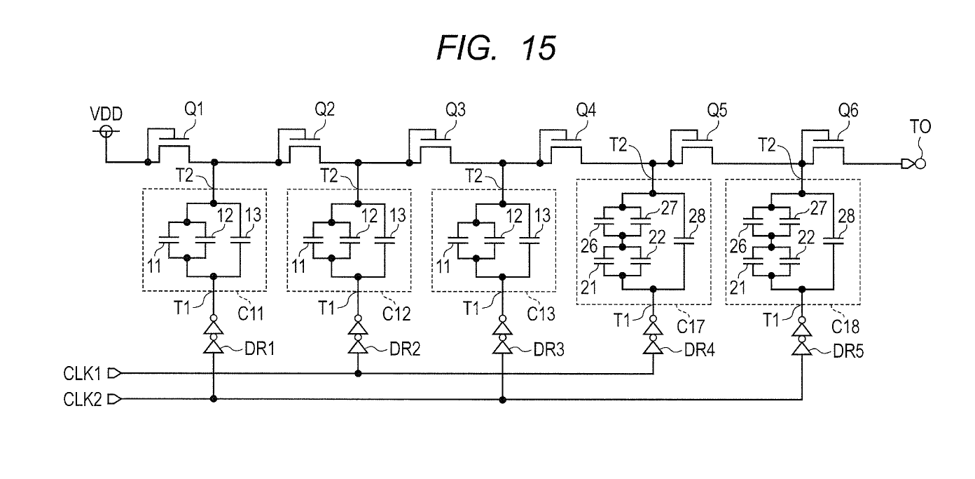

FIG. 15 is a circuit diagram depicting a configuration of a charge pump circuit according to a second embodiment of the present application; this figure is contrasted with FIG. 7. Referring to FIG. 15, this charge pump circuit differs from the charge pump circuit in FIG. 7 in the following respect: the high voltage withstanding capacitors C14, C15 are replaced by high voltage withstanding capacitors C17, C18, respectively.

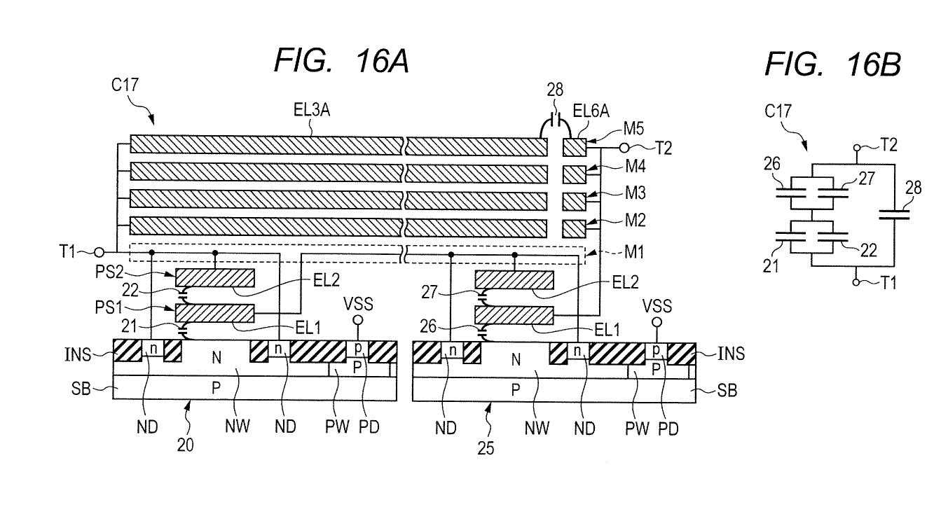

FIG. 16A is a cross-sectional diagram depicting the structure of a high voltage withstanding capacitor C17; this figure is contrasted with FIG. 8A. FIG. 16B is a schematic depicting the circuitry of the capacitor C17; this figure is contrasted with FIG. 8B. In FIGS. 16A and 16B, the capacitor C17 has three capacitor elements 20, 25, 28 and two terminals T1, T2.

The capacitor elements 20, 25 each have a structure similar to a dual gate type transistor, like the capacitor element 10 depicted in FIG. 5. The capacitor element 20 includes two capacitor elements 21, 22. The capacitor element 25 includes two capacitor elements 26, 27. Capacitor elements 21, 26 each have a fifth capacitance value that is determined by the planar dimension of an area in which an electrode EL1 and a N-type well NW face each other, the distance between the electrode EL1 and the N-type well NW, and the permittivity (dielectric constant) of a first insulation layer (not depicted). Capacitor elements 22, 27 each have a sixth capacitance value that is determined by the planar dimension of an area in which an electrode EL1 and an electrode EL2 face each other, the distance between the electrodes EL1, EL2, and the permittivity (dielectric constant) of a second insulation layer (not depicted). The fifth capacitance value and the sixth capacitance value are equal.

The capacitor element 28 has the same structure as the high voltage withstanding MIM-type capacitor element 14 depicted in FIG. 13. The capacitor element 28 includes multiple arrays of electrodes EL3A, EL4A formed over the capacitor elements 20, 25. The capacitor element 28 has a seventh capacitance value that is determined by the planar dimension of an area in which the electrodes EL3A, EL4A face each other, the distance between the electrodes EL3A, EL4A, the permittivity (dielectric constant) of a third insulation layer (not depicted) between the electrodes EL3A, EL4A, and the number of the electrodes EL3A, EL4A facing each other.

In this capacitor C17, the n-type impurity diffused layer ND and the electrode EL2 of the capacitor element 20 and each electrode EL5A (in other words, each electrode EL3A) are coupled to the terminal T1. The electrode EL1 of the capacitor element 20 and the n-type impurity diffused layer ND and the electrode EL2 of the capacitor element 25 are inter-coupled. The electrode EL2 of the capacitor element 25 and each electrode EL6A (in other words, each electrode EL4A) are coupled to the terminal 2. For example, the terminal T1 is coupled to a “Low” level side and the terminal T2 is coupled to a “High” level side. This capacitor C17 includes two capacitor elements 21, 26 coupled in series between the terminals T1, T2, two capacitor elements 22, 27 coupled in series between the terminals T1, T2, and the capacitor element 28 coupled between the terminals T1, T2.

Other details of configuration and operation are the same as the first embodiment and therefore their description is not repeated. In this second embodiment also, the same advantageous effects can be obtained as with the first embodiment.

### Third Embodiment

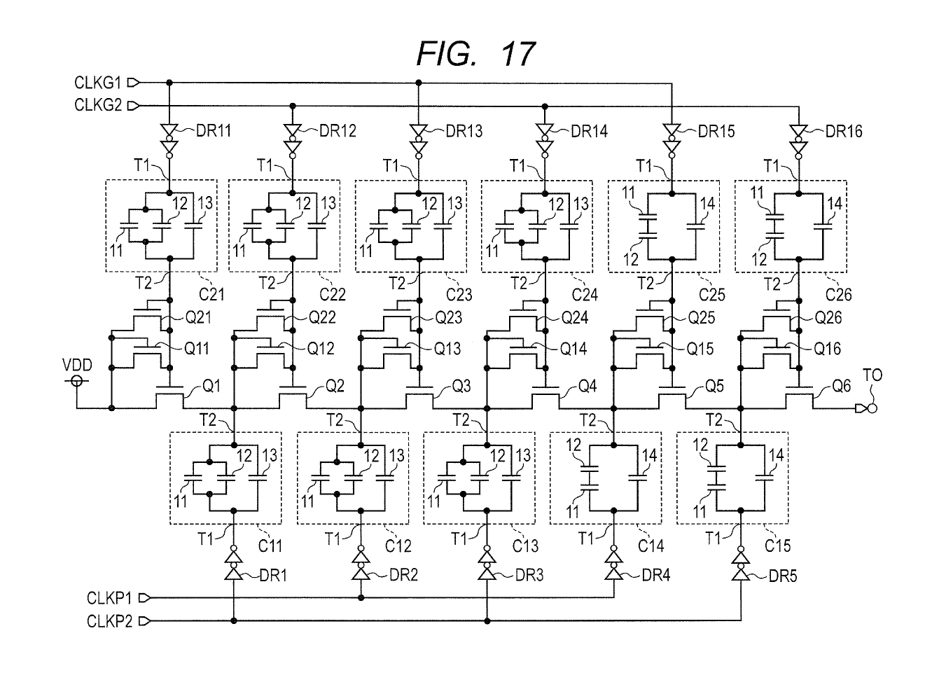

FIG. 17 is a circuit diagram depicting a configuration of a charge pump circuit according to a third embodiment of the present application; this figure is contrasted with FIG. 7. Referring to FIG. 17, this charge pump circuit differs from the charge pump circuit in FIG. 7 in the following respect: N-channel MOS transistors Q11 to Q16, Q21 to Q26 and drivers DR11 to DR16 are added. Besides, the clock signals CLK1, CLK2 are replaced by clock signals CLKP1, CLKP2, respectively, and clock signals CLKG1, CLKG2 are newly introduced.

For each of the transistors Q11 to Q16, its gate and drain are coupled to each other. The drains of the transistors Q11 to Q16 are coupled to the drains of the transistors Q1 to Q6, respectively. The sources of the transistors Q11 to Q16 are coupled to the gates of the transistors Q1 to Q6, respectively. Each of the transistors Q11 to Q16 operates as a diode; its gate and drain act as an anode and its source acts as a cathode.

For each of the transistors Q21 to Q26, its gate and drain are coupled to each other. The sources of the transistors Q21 to Q26 are coupled to the drains of the transistors Q1 to Q6, respectively. The drains of the transistors Q21 to Q26 are coupled to the gates of the transistors Q1 to Q6, respectively. Each of the transistors Q21 to Q26 operates as a diode; its gate and drain act as an anode and its source acts as a cathode.

One end terminals T1 of capacitors C21 to C26 receive clock signals output from drivers DR11 to DR16, respectively, and their other end terminals T2 are coupled to the gates of the transistors Q1 to Q5, respectively. A clock signal CLKG1 is supplied to odd-numbered drivers DR11, DR13, DR15. A clock signal CLKG2 is supplied to even-numbered drivers DR12, DR14, DR16.

The capacitors C21 to C24 each are ordinary voltage withstanding capacitors and their structure is the same as the capacitor C11. The capacitors C25, C26 each are high voltage withstanding capacitors and their structure is the same as the capacitor C14. However, the capacitance value of each of the capacitors C21 to C26 is on the order of one-tenth of the capacitance value of each of the capacitors C11 to C15.

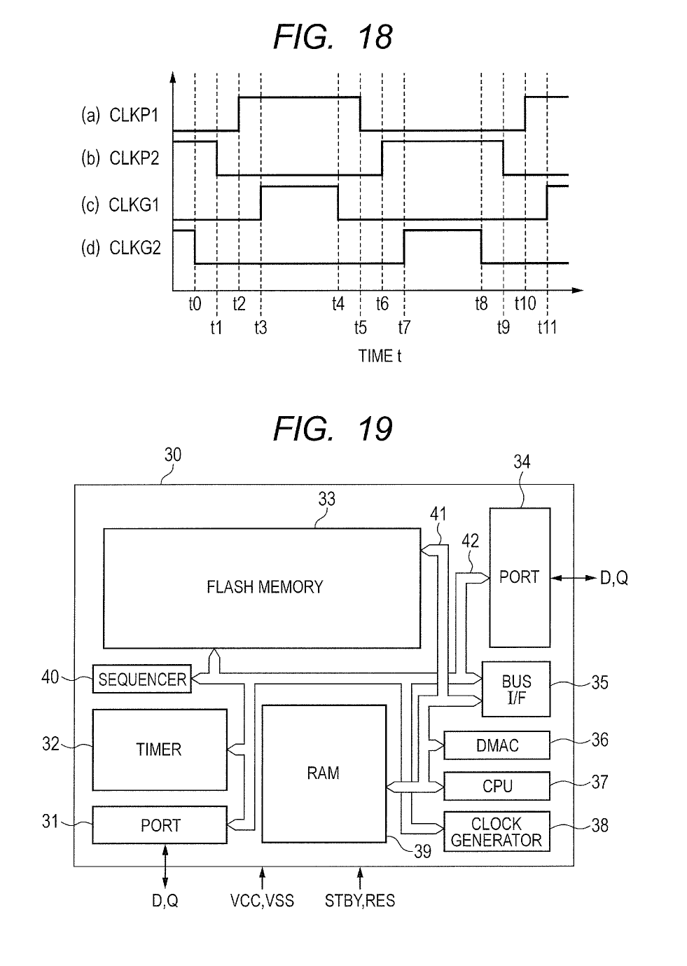

FIGS. 18, A to 18D, is a diagram presenting the waveforms of the clock signals CLKP1, CLKP2, CLKG1, CLKG2. In FIGS. 18, A to 18D, the clock signals CLKP1 and CLKP2 change to “High” level alternately. For each of the clock signals CLKP1, CLKP2, its “Low” level period is longer than its “High” level period. There is a period when both the clock signals CLKP1 and CLKP2 are “L” level.

The “High” level periods of the clock signals CLKP1, CLKP2 are longer than the “High” level periods of the clock signals CLKG1, CLKG2, respectively. The clock signals CLKG1, CLKG2 change to “High” level during the “High” level periods of the clock signals CLKP1, CLKP2, respectively. The phases of the clock signals CLKP1, CLKP2 shift by 180 degrees from each other. The phases of the clock signals CLKG1, CLKG2 shift by 180 degrees from each other.

Then, operation of this charge pump circuit is described. First, in a state when all the clock signals CLKP1, CLKP2, CLKG1, CLKP2 are “Low” level, the clock signal CLKP1 rises to “High” level (at time t2). Thereby, capacitance coupling of the capacitors C12, C14 causes the source voltage of the transistors Q2, Q4 to rise.

In turn, the clock signal CLKG1 rises to “High” level (at time t3) and capacitance coupling of the capacitors C21, C23, C25 causes the gate voltage of the transistors Q1, Q3, Q5 to rise, thus turning the transistors Q1, Q3, Q5 on. Thereby, current flows through the transistor Q1 and the capacitor C11 is charged. Current also flows through the transistors Q3, Q5 by which the charges of the capacitors C12, C14 are transferred to the capacitors C13, C15, respectively.

Then, the clock signal CLKG1 falls to “Low” level (at time t4) and capacitance coupling of the capacitors C21, C23, C25 causes the gate voltage of the transistors Q1, Q3, Q5 to fall, thus turning the transistors Q1, Q3, Q5 off. In turn, the clock signal CLKP1 falls to “Low” level (at time t5) and capacitance coupling of the capacitors C12, C14 causes the source voltage of the transistors Q2, Q4 to fall.

Then, in a state when all the clock signals CLKP1, CLKP2, CLKG1, CLKG2 are “Low” level, the clock signal CLKP2 rises to “High” level (at time t6). Thereby, capacitance coupling of the capacitors C11, C13, C15 causes the source voltage of the transistors Q1, Q3, Q5 to rise.

In turn, the clock signal CLKG2 rises to “High” level (at time t7) and capacitance coupling of the capacitors C22, C24, C26 causes the gate voltage of the transistors Q2, Q4, Q6 to rise, thus turning the transistors Q2, Q4, Q6 on. Thereby, current flows through the transistors Q2, Q4, Q6 by which the charges of the capacitor C11, C13 are transferred to the capacitor C12, C14, respectively, and the charge of the capacitor 15 is supplied to the output terminal TO.

Then, the clock signal CLKG2 falls to “Low” level (at time t8) and capacitance coupling of the capacitors C22, C24, C26 causes the gate voltage of the transistors Q2, Q4, Q6 to fall, thus turning the transistors Q2, Q4, Q6 off. In turn, the clock signal CLKP2 falls to “Low” level (at time t9) and capacitance coupling of the capacitors C11, C13, C15 causes the source voltage of the transistors Q1, Q3, Q5 to fall. This operation is repeated and the voltage of the output terminal TO gradually rises.

The voltage of the output terminal TO is compared to a target voltage by a comparator (not depicted). When the voltage of the output terminal TO becomes equal to or more than the target voltage, the clock signals CLKP1, CLKP2, CLKG1, CLKG2 are shut off and the operation of the charge pump circuit is stopped. When the voltage of the output terminal TO becomes lower than the target voltage, the clock signals CLKP1, CLKP2, CLKG1, CLKG2 are supplied and the operation of the charge pump circuit is restarted. In this way, the voltage of the output terminal TO is maintained at the target voltage.

This charge pump circuit is called a gate boost type charge pump circuit. In the charge pump circuit in FIG. 7, for each of the transistors Q1 to Q6, its voltage drops by a threshold voltage of the transistor Q. In the charge pump circuit of the third embodiment, however, such a voltage drop does not occur and, thus, higher charge transfer efficiency can be obtained than in the charge pump circuit in FIG. 7.

### Fourth Embodiment

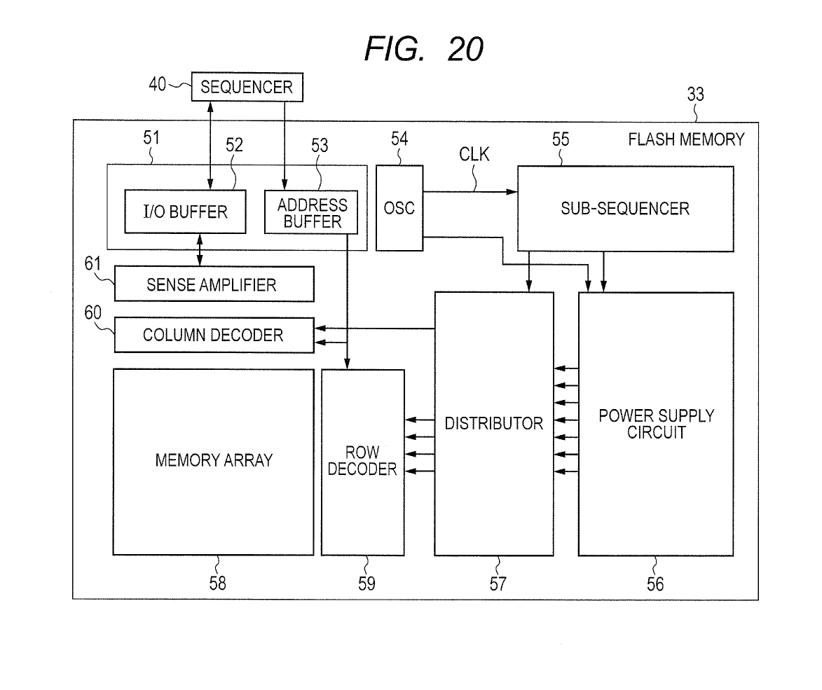

FIG. 19 is a block diagram depicting a configuration of a microcomputer 30 according to a fourth embodiment of the present application. In FIG. 19, the microcomputer 30 has ports 31, 34, a timer 32, a flash memory 33, a bus interface (bus IF) 35, and a DMAC (Direct Memory Access Controller) 36. Besides, the microcomputer 30 includes a CPU (Central Processing Unit) 37, a clock generator 38, a RAM (Random Access Memory) 39, and a sequencer 40. Although not restrictive, the microcomputer 30 is formed over the surface of a semiconductor substrate such as a single crystal silicon substrate by semiconductor integrated circuit fabrication technology which is publicly known. The microcomputer 30 and the semiconductor substrate make up a semiconductor device.

The ports 31, 34, timer 32, sequencer 40, flash memory 33, bus interface 35, and clock generator 38 are inter-coupled by a peripheral bus 42. The RAM 39, flash memory 33, bus interface 35, DMAC 36, and CPU 37 are inter-coupled by a high-speed bus 41.

The ports 31, 34 each take in data signals DI from outside and outputs data signals DO to outside. The timer 32 measures time by counting clock pulses. The DMAC 36 implements control for direct data transfer between different devices without intervention of the CPU 37. The clock generator 38 includes an oscillator that produces a clock signal of a predetermined frequency and a PLL (Phase Locked Loop) circuit for multiplying the clock signal produced by the oscillator.

The microcomputer 30 transits into a standby state in response to a standby signal STBY and is initialized in response to a reset signal RES. As power supply voltage for the operation of the microcomputer 30, a power supply voltage VCC and a ground voltage VSS are supplied externally. The sequencer 40 sequentially controls the operation of the flash memory 33 according to an instruction from the CPU 37.

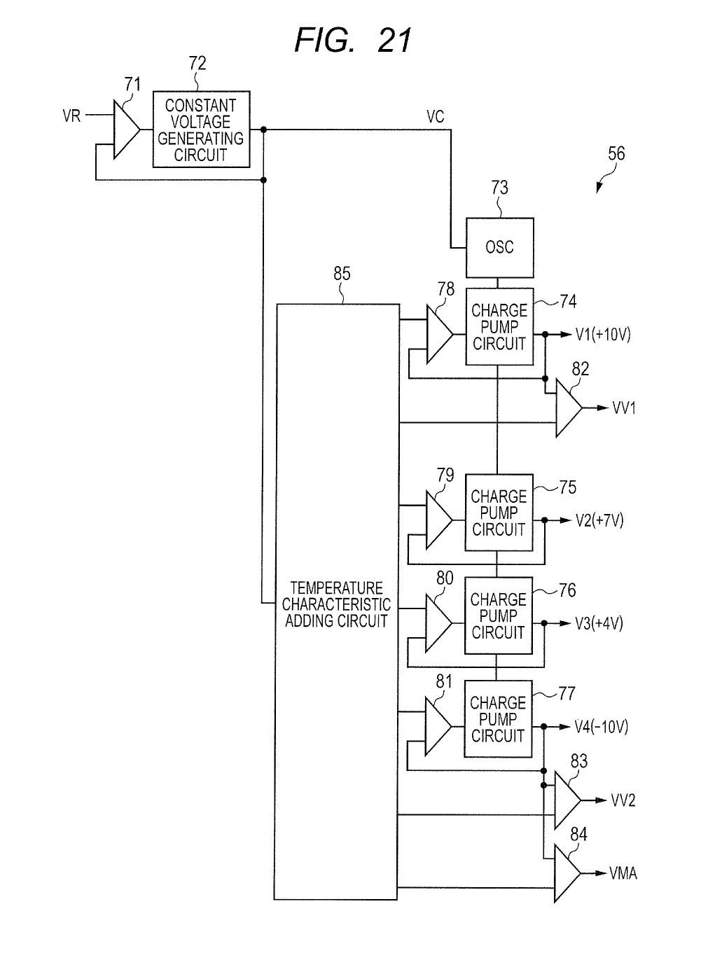

FIG. 20 is a block diagram depicting a configuration of the flash memory 33. In FIG. 20, the flash memory 33 includes, an I/O control circuit 51, an oscillator (OSC) 54, a sub-sequencer 55, a power supply circuit 56, and a distributor 57. Besides, the flash memory 33 includes a memory array 58, a row decoder 59, a column decoder 60, and a sense amplifier 61.

The I/O control circuit 51 has a function of controlling signal input/output to/from the flash memory 33 and includes an I/O buffer 52 and an address buffer 53. The oscillator 54 generates a clock signal CLK. This clock CLK is transferred to the sub-sequencer 55 and the power supply circuit 56. The sub-sequencer 55 sequentially controls the operation of the distributor 57 and the power supply circuit 56.

The power supply circuit 56 includes a plurality of charge pump circuits for producing voltages that differ from each other. The charge pump circuits enter an operating state or an non-operating state in response to an on/off control signal from the sub-sequencer 55. A plurality of voltages produced by the charge pump circuits are transferred to the row decoder 59 and the column decoder 60 via the distributor 57.

The row decoder 59 decodes a row address signal from the address buffer 53 and drives a word line in the memory array 58 to a select level. The column decoder 60 decodes a column address signal from the address buffer 53 and produces a column select signal. The sense amplifier 61 compares a signal that is selectively output from the memory array 58 according to an output of the column decoder 60 to a reference level and obtains a readout data signal DO.

The memory array 58 includes a plurality of flash memory cells arranged in multiple rows and columns. Each of the flash memory cells has the respective electrodes of a control gate, a floating gate, a drain, and a source. The floating gate is formed by using the first polysilicon layer PS1 and the control gate is formed by using the second polysilicon layer PS2.

For flash memory cells arranged in a column direction, their drains are commonly coupled to a bit line via a sub bit line selector. The sources of the flash memory cells are coupled to a common source line. The flash memory cells coupled to a common source line make up one block and these cells are formed within a common well area of a semiconductor substrate and treated as a unit of erasure. On the other hand, for flash memory cells arranged in a row direction, their control gates are coupled to a word line in a row-by-row basis.

FIG. 21 is a block diagram depicting a configuration of the power supply circuit 56. In FIG. 21, the power supply circuit 56 includes operational amplifiers 71, 82 to 84, comparators 78 to 81, a constant voltage generating circuit 72, an oscillation circuit (OSC) 73, and charge pump circuits 74 to 77. An operational amplifier 71 compares a reference voltage VR1 and a voltage VC output by the constant voltage generating circuit 72 and controls the constant voltage generating circuit 72, based on a result of the compassion. The reference voltage VR is, for example, 1.2 V. Controlled by the operational amplifier 71, the constant voltage generating circuit 72 outputs a constant voltage VC at the same level as the reference voltage VR.

The oscillation circuit 73 generates a clock signal of a predetermined frequency, based on the constant voltage VC from the constant voltage generating circuit 72. This clock signal is transferred to the charge pump circuits 74 to 77. A temperature characteristic adding circuit 85 adds a predetermined temperature-dependent characteristic to the constant voltage VC, thus generating a constant voltage VCT. This constant voltage VCT is supplied to comparators 78 to 81.

A comparator 78 compares a voltage V1 output by a charge pump circuit 74 and the voltage VCT output by the temperature characteristic adding circuit 85 and controls the charge pump circuit 74, based on a result of the comparison. Controlled by the comparator 78, the charge pump circuit 74 generates a memory rewriting voltage V1. This memory rewriting voltage V1 is assumed to be, e.g., +10 V. An operational amplifier 82 adds the constant voltage VCT to the voltage V1 output by the charge pump circuit 74, thus generating a verify voltage VV1.

A comparator 79 compares a voltage V2 output by a charge pump circuit 75 and the voltage VCT output by the temperature characteristic adding circuit 85 and controls the charge pump circuit 75, based on a result of the comparison. Controlled by the comparator 79, the charge pump circuit 75 generates a memory rewriting voltage V2. This memory rewriting voltage V2 is assumed to be, e.g., +7 V.

A comparator 80 compares a voltage V3 output by a charge pump circuit 76 and the voltage VCT output by the temperature characteristic adding circuit 85 and controls the charge pump circuit 76, based on a result of the comparison. Controlled by the comparator 80, the charge pump circuit 76 generates a memory rewriting voltage V3. This memory rewriting voltage V3 is assumed to be, e.g., +4 V.

A comparator 81 compares a voltage V4 output by a charge pump circuit 77 and the voltage VCT output by the temperature characteristic adding circuit 85 and controls the charge pump circuit 77, based on a result of the comparison. Controlled by the comparator 81, the charge pump circuit 77 generates a memory rewriting voltage V4. This memory rewriting voltage V4 is assumed to be, e.g., −10 V.

An operational amplifier 83 adds the voltage VCT output by the temperature characteristic adding circuit 85 to the voltage V4 output by the charge pump circuit 77, thus generating a verify voltage VV2. An operational amplifier 84 adds the voltage VCT output by the temperature characteristic adding circuit 85 to the voltage V4 output by the charge pump circuit 77, thus generating a memory array control voltage VMA. In each of the charge pump circuits 74 to 77, the capacitors presented in the first through third embodiments are used.

In this fourth embodiment also, the same advantageous effects can be obtained as with the first through third embodiments. It is indisputable that the foregoing first through fourth embodiments and the example of modification may be combined appropriately.

While the invention made by the present inventors has been described specifically based on its embodiments hereinbefore, it will be appreciated that the present invention is not limited to the described embodiments and various modifications may be made thereto without departing from the scope of the invention.

What is claimed is:

1. A capacitor comprising:
a first electrode formed by using a first polysilicon layer over a semiconductor substrate;
a second electrode formed by using a second polysilicon layer over the first polysilicon layer; and
third and fourth electrodes formed by using a metal wiring layer over the second polysilicon layer,
wherein the semiconductor substrate and the first electrode are provided facing each other and make up a first capacitor element;
wherein the first and second electrodes are provided facing each other and make up a second capacitor element, and
wherein the third and fourth electrodes are provided side by side and make up a third capacitor element.

2. The capacitor according to claim 1,
wherein a plurality of pairs of the third and fourth electrodes are formed by using the metal wiring layer,
wherein each third electrode extends in a first direction and each fourth electrode extends in the first direction,
wherein the pairs of the third and fourth electrodes are arranged in a second direction at right angles to the first direction,
wherein the capacitor further comprises fifth and sixth electrodes formed by using the metal wiring layer,
wherein the fifth electrode extends in the second direction and is disposed on one end side of the pairs of the third and fourth electrodes and coupled to each third electrode, and
wherein the sixth electrode extends in the second direction and is disposed on the other end side of the pairs of the third and fourth electrodes and coupled to each fourth electrode.

3. The capacitor according to claim 2,
wherein a plurality of metal wiring layers are provided,
wherein the third through sixth electrodes are formed by using the respective metal wiring layers,
wherein a plurality of layers of the third through sixth electrodes are arranged in a third direction vertical to the surface of the semiconductor substrate, and
wherein a plurality of fifth electrodes are coupled to each other and a plurality of sixth electrodes are coupled to each other.

4. The capacitor according to claim. 1, further comprising first and second terminals,
wherein the first and second capacitor elements are coupled in series or in parallel, and
wherein the third capacitor element as well as the first and second capacitor elements is coupled between the first and second terminals.

5. The capacitor according to claim 4,
wherein the first terminal is coupled to the semiconductor substrate and the second and third electrodes,
wherein the second terminal is coupled to the first and fourth electrodes, and
wherein the first through third capacitor elements are coupled in parallel between the first and second terminals.

6. The capacitor according to claim 4,
wherein the first terminal is coupled to the semiconductor substrate and the third electrode,
wherein the second terminal is coupled to the second and fourth electrodes,
wherein the first and second capacitor elements are coupled in series between the first and second terminals, and
wherein the third capacitor element is coupled between the first and second terminals.

7. The capacitor according to claim 4,
wherein the first terminal is coupled to the semiconductor substrate and the second electrode,
wherein the second terminal is coupled to the third electrode,
wherein the first and fourth electrodes are coupled to each other,
wherein the first and third capacitor elements are coupled in series between the first and second terminals, and
wherein the second capacitor element is coupled in parallel with the first capacitor element.

8. The capacitor according to claim 4,
wherein two pairs of the first and second electrodes are provided,
wherein the third and fourth electrodes are provided over the two pairs of the first and second electrodes,
wherein the first electrode of a first pair of the two pairs is provided facing a first well within the semiconductor substrate and the first electrode of a second pair of the two pairs is provided facing a second well within the semiconductor substrate,
wherein the first terminal is coupled to the first well, the third electrode, and the second electrode of the first pair,
wherein the first electrode of the first pair, the second well, and the second electrode of the second pair are inter-coupled,
wherein the second terminal is coupled to the fourth electrode and the first electrode of the second pair,
wherein the first capacitor elements of the first and second pairs are coupled in series between the first and second terminals,
wherein the second capacitor elements of the first and second pairs are coupled in series between the first and second terminals, and
wherein the third capacitor element is coupled between the first and second terminals.

9. A charge pump circuit comprising:
M capacitors (where M is an integer of 2 or more), each capacitor being configured according to claims 4; and
1st through (M+1)-th diodes coupled in series,
wherein one end terminal of the first and second terminals of the M capacitors is coupled to a cathode of the 1st through (M+1)-th diodes, respectively,
wherein the other end terminal of the capacitors coupled to the cathodes of odd-numbered diodes respectively receives a first clock signal,
wherein the other end terminal of the capacitors coupled to the cathodes of even-numbered diodes respectively receives a second clock signal, and
wherein the first and second clock signals are phase shifted by 180 degrees from each other.

10. The charge pump circuit according to claim 9,
wherein one subset of the 1st through (M+1)-th diodes outputs a voltage whose absolute value is larger than an output voltage of the other subset of the diodes, the first and second capacitor elements are coupled in series in the capacitors coupled to the cathodes of the one subset of the diodes, and the first and second capacitor elements are coupled in parallel in the capacitors coupled to the cathodes of the other subset of the diodes.

11. A charge pump circuit comprising:
(2M+1) capacitors (where M is an integer of 2 or more), each capacitor being configured according to claims 4; and
1st through (M+1)-th transistors coupled in series,
wherein one end terminal of the first and second terminals of M ones of the capacitors is coupled to a source of the 1st through M-th transistors, respectively,
wherein the other end terminal of the capacitors corresponding to odd-numbered transistors receives a first clock,
wherein the other end terminal of the capacitors corresponding to even-numbered transistors receives a second clock,
wherein one end terminal of the first and second terminals of the remaining (M+1) ones of the capacitors (a second subset) is coupled to a gate of the 1st through (M+1)-th transistors, respectively,
wherein the other end terminal of the second subset of the capacitors corresponding to odd stages of transistors receives a third clock signal,
wherein the other end terminal of the second subset of the capacitors corresponding to even stages of transistors receives a fourth clock signal,
wherein the first and second clock signals are phase shifted by 180 degrees from each other,
wherein the third and fourth clock signals are phase shifted by 180 degrees from each other, and
wherein the first and third clock signals are phase shifted by 180 degrees from each other.

12. The charge pump circuit according to claim 11,
wherein one subset of the 1st through (M+1)-th transistors outputs a voltage whose absolute value is larger than an output voltage of the other subset of the transistors, the first and second capacitor elements are coupled in series in the capacitors coupled to the drains or gates of the one subset of the transistors, and the first and second capacitor elements are coupled in parallel in the capacitors coupled to the drains or gates of the other subset of the diodes.

13. A semiconductor device comprising:
a semiconductor substrate; and
a charge pump circuit that is formed over the semiconductor substrate and boots a power supply voltage to a predetermined step-up voltage,
the charge pump circuit comprising:
N transistors for transferring electric charge (where N is an integer of 2 or more) coupled in series between a power supply voltage terminal and an output voltage terminal; and
(N−1) step-up capacitors, each comprising a first terminal that receives a clock signal and a second terminal that is coupled to a series-coupling node between transistors for transferring electric charge,
each of the step-up capacitors comprising:
a layered capacitor having first and second polysilicon layers deposited with an insulation film in between over a well area of the semiconductor substrate, and
a MIM capacitor placed just over the layered capacitor and formed by using a metal wiring layer above the second polysilicon layer.

14. The semiconductor device according to claim 13,
wherein each of the step-up capacitors comprises a first electrode formed by using the first polysilicon layer of the layered capacitor, a second electrode formed by using the second polysilicon layer, and third and fourth electrodes formed such that their longitudinal lateral sides face each other, spaced by a predetermined interval, by using the metal wiring layer of the MIM capacitor,
wherein, among the (N−1) step-up capacitors, in step-up capacitors that are coupled to 1st through K-th series-coupling nodes (where K is an integer larger than 1 and smaller than (N−1)) from the power supply voltage terminal side, the first and fourth electrodes are coupled in common to the second terminal and the well area and the second and third electrodes are coupled in common to the first terminal, and
wherein, in step-up capacitors that are coupled to (K+1)-th through (N−1)-th series-coupling nodes, the second and fourth electrodes are coupled in common to the first terminal and the well area and the third electrode are coupled in common to the second terminal.

15. The semiconductor device according to claim 14,
wherein said predetermined interval in the step-up capacitors that are coupled to 1st through K-th series-coupling nodes is smaller than said predetermined interval in the step-up capacitors that are coupled to (K+1)-th through (N−1)-th series-coupling nodes.

16. The semiconductor device according to claim 13, further comprising a plurality of memory cells that are formed over the semiconductor substrate, each memory cell comprising a dual gate type transistor having first and second gates,
wherein the first and second gates are formed by using the first and second polysilicon layers, respectively.
